(19) United States
(12) Patent Application Publication
(10) Pub. No.: US 2020/0156865 A1
(43) Pub. Date: May 21, 2020

(54) SMART CONTAINERS OR JARS

(71) Applicants: V D Sham DAYAL, Hyderabad (IN); Shailaja KESARY, Telangana (IN); Jyothsna DAYAL, Telangana (IN)

(72) Inventors: V D Sham DAYAL, Hyderabad (IN); Shailaja KESARY, Telangana (IN)

(21) Appl. No.: 16/625,622

(22) PCT Filed: Oct. 21, 2017
(86) PCT No.: PCT/IB2017/056555

§ 371 Date: Dec. 20, 2019

(30) Foreign Application Priority Data
Jul. 3, 2017 (IN) 201741023317

(51) Int. Cl. B65D 90/48; G01G 19/413; H03H 9/72

(52) U.S. Cl. CPC B65D 90/48; H03H 9/725; G01G 19/413

(57) ABSTRACT

Smart containers or jars are devices that will be used to keep track of various parameters regarding the food stored in them like the weight, count, food quality, nutritional facts, expiry date, minimum order level and all other food related parameters. These devices work as ordinary jars with enablement to track the food related parameters mentioned above. These devices will be equipped with a micro-computer which will be connected to a wireless or Cabled Internet of the user's premises and in turn update the food related parameters to a web application which comes with this device. The data is then processed in the web application and alerts are sent to a mobile device of the user on the various food related parameters.

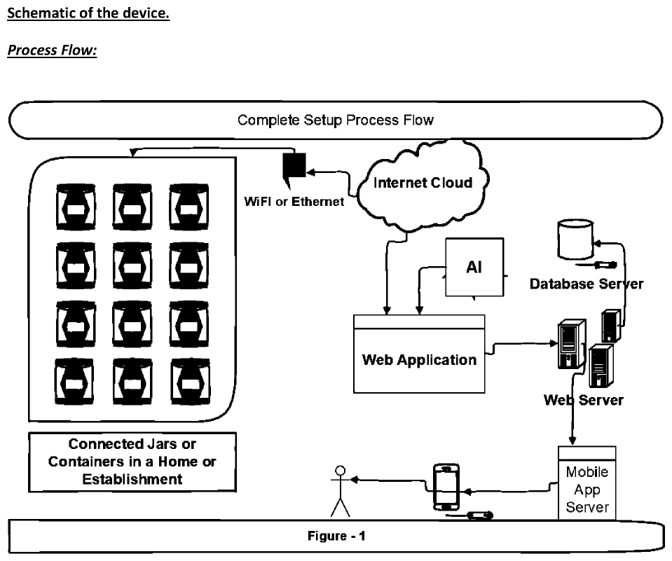

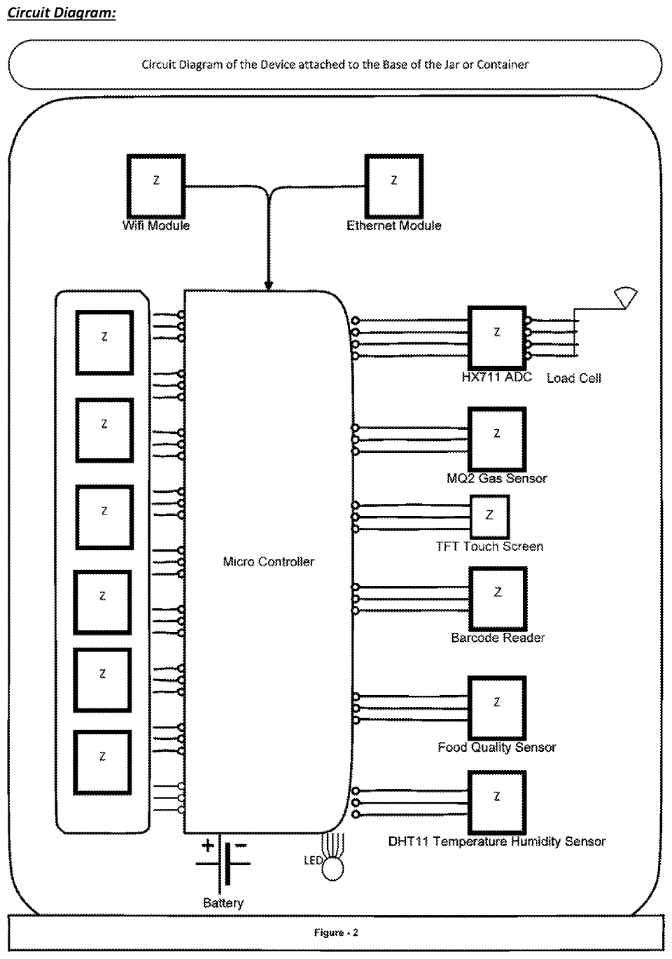

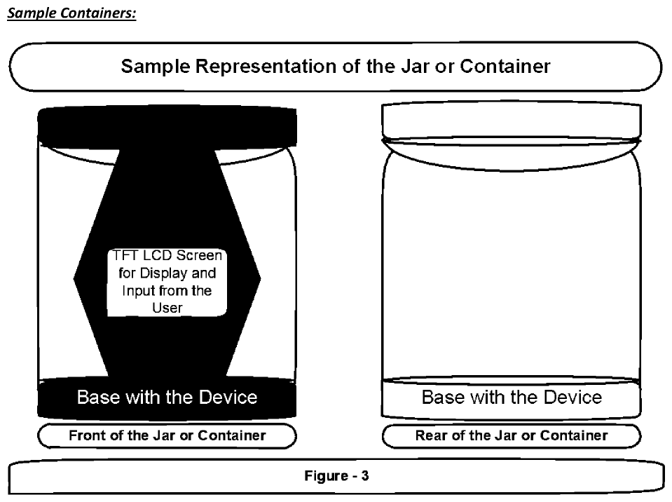

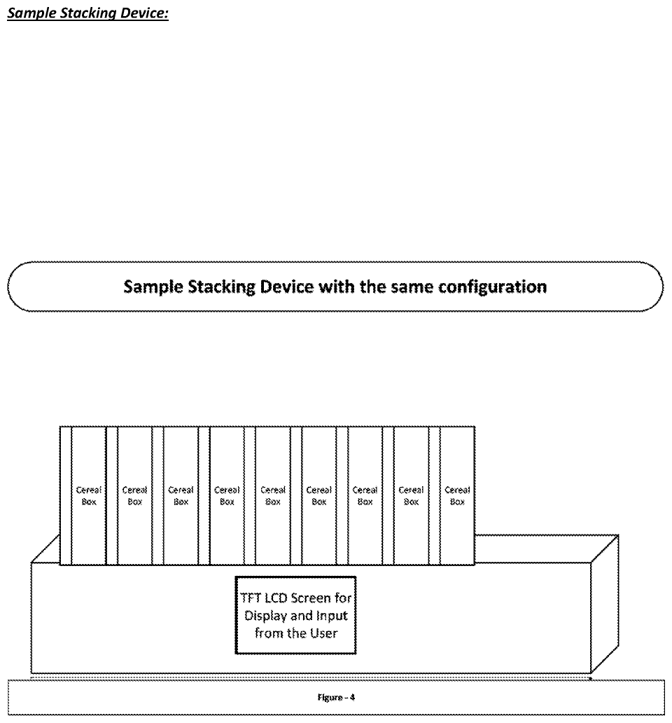

Currently the users of this device do a physical verification of the contents of the jars in their house or establishment to check the availability, quality and other food related parameters on the packaging of the products. By introducing these smart jars or containers users can check all these food related parameters for all the food available at their home or establishment on their mobile devices and take appropriate action like ordering for more or discarding the expired items or simply planning for a meal and even more.

These smart devices will enable people to be more efficient in their home food management or establishment inventory management, avoiding unnecessary health complications on consuming or selling expired food items or bad quality food items.

These jars and containers can be used to store raw food from the stores and even cooked food. There are many other possibilities with these jars like when they are integrated with recipes the user can actually check out the possible recipes that they can cook with the available good quality food in their house and when integrated with Artificial Intelligence the connected devices can actually tell the users the best possible recipes to avoid food wastage. And from another aspect the stores will get information through Artificial Intelligence on the optimal inventory configuration for the store considering the place, weather conditions and other parameters enabling better inventory management leading to better profits.

The most important aspect of these devices will be to reduce food wastage which happens everywhere. For example in a home it is generally seen that people stock food and are not aware of the expiry date until they actually pick it up from the shelf to either use it in cooking or for direct consumption which leads to a lot of wastage. These devices can alert the users of the expiring items in their homes so as to enable the users to better manage their consumption and reduce wastage.

The same thing applies to small and medium grocery stores where the food is stocked based on re-order levels and less importance is given to the expiry of the items. Most of the items nearing expiry date is simply wasted or sold to un-informed customers. Instead these devices will alerts the establishment owners of the expiring items and this information can be used along with their sales patterns and donated to the charity organisations for immediate consumption.

The other thing that can be achieved with these devices is that after collecting data of the homes and establishment's artificial intelligence can be triggered to achieve the most optimum levels of inventory at the establishments based on their sales patterns and even at homes based on their consumption levels, thereby, minimising the waste in food and the reducing the costs of their groceries.

One more important aspect of these devices is that once these are equipped with the nutritional facts of the food on the shelves of the users the application can then give inputs to the users on the best possible recipes based on their diet patterns and other personality factors of the users.

For example, many of the food products are supposed to be stored in a controlled temperature and humidity environment for them to be in their original form or be edible. These devices can alert the users of the drastic change in the temperature and humidity levels inside these jars and in the outside environment so as to enable the users to secure the food items from going waste and become non edible or simply for not losing their original form.

These jars will be equipped with a dispenser which would enable the user to dispense the ingredient to the required quantity based on a recipe or just by inputting the requirement into the touch screen monitor.

There are many more advantages of these devices and that only a few are mentioned above is to be noted.

What is claimed is:

1. Smart jar or container equipped with a micro-controller connected to the internet either through the Wi-Fi or through a Ethernet cable. The jars or containers can be made in any material, plastic, glass, metal or any other food grade composite material and in any shape and form as may be suitable for the use by users. The processing unit can be made of any combination of micro-controllers and sensors which are currently available in the market and those that will be introduced later in a similar or much better configuration. This would enhance the usability of the devices and add more features to the devices.

2. Dispenser for the Smart Jar which will be a combination of electronic solenoid valve, flow sensor and a tube to dispense the ingredients.

3. Smart Stacker which will be equipped with a micro-computer connected to the internet either through a Wi-Fi or through an Ethernet cable. The stacker can be made with any kind of material to stack boxes.

4. The Web Application which receives raw data from each of these devices and processes it to derive intelligent information from the raw data and process it and store information in a Database. The Web Application can be written in any software program available in the market as to enable a smooth experience to the customer and is not limited to any software program or platform or Operating system or any such inventions that will come up in the future.

5. The Artificial Intelligence engine which process the raw data to derive meaningful conclusions. The Artificial Intelligence engine can be built with any current available technologies and any combination of them available in the market today and any future technologies or platforms or operating systems for these devices.

6. The Database itself which stores information regarding the food parameters and other nutritional facts and personality facts of the users. The Database can be built on any form of the currently available database systems or any other future database systems that would be introduced in the market.

7. The Mobile Application which pulls the processed data from the Database and give information to the users. The mobile application can be written in any platform or operating system, device or any other devices that will be introduced in the market in future.

8. For the entire device and the ecosystem, the use of it is not limited to general consumers or grocery stores and that it can be used by any other establishment in future if there is a use for the same in those type of establishment or persons.

9. For the entire device and the ecosystem and the data contained therein would be the sole proprietary information of the patent holder with the general caveat of adhering to the privacy policies existing in the country of use.
